(19) United States
(12) Patent Application Publication
(10) Pub. No.: US 2008/0318085 A1
(43) Pub. Date: Dec. 25, 2008

(54) METHOD OF FORMING A PROTECTIVE FILM AND A MAGNETIC RECORDING MEDIUM HAVING A PROTECTIVE FILM

(75) Inventors: Tuqiang LI, Nagano (JP); Masaki MIYAZATO, Nagano (JP); Tsuyoshi ONITSUKA, Tokyo (JP); Makoto ISOZAKI, Nagano (JP); Hajime KURIHARA, Tokyo (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/137,447

(22) Filed: Jun. 11, 2008

(30) Foreign Application Priority Data
Jun. 12, 2007 (JP) 2007-155332

(51) Int. Cl. G11B 5/62; C23C 16/513

(52) U.S. Cl. 428/800; 427/577

(57) ABSTRACT

A method of forming a carbon protective film is disclosed that improves electromagnetic conversion characteristics through reduction of the film thickness without any damage on a magnetic layer. Also disclosed is a magnetic recording medium that exhibits good electromagnetic conversion characteristics and corrosion resistance. The method of forming the carbon protective film uses a high frequency plasma CVD method on a disk including at least a magnetic film on a nonmagnetic substrate. A bias voltage in a range of −200 V to zero V is applied at the beginning of discharge in a process of forming the carbon protective film, and a bias voltage in a range of −500 V to −200 V is applied at the end of discharge. Also disclosed is a magnetic recording medium having at least a magnetic film and a protective film on a nonmagnetic substrate, wherein the protective film is formed by the method of forming a protective film stated above according to the invention.

### CROSS REFERENCE TO RELATED APPLICATIONS

This application is based on, and claims priority to, Japanese Patent Application No. 2007-155332, filed on Jun. 12, 2007, the contents of which are incorporated herein by reference in their entirety.

### BACKGROUND OF THE INVENTION

A. Field of the Invention

The present invention relates to a method of forming a protective film and a magnetic recording medium having a protective film.

B. Description of the Related Art

A conventional magnetic recording medium comprises a nonmagnetic substrate, a nonmagnetic underlayer film, an intermediate film, and a magnetic film, the latter three films being provided on a substrate. A protective film is formed by CVD or PVD on the magnetic film, and a film of a lubricant such as perfluoropolyether is provided on the protective film.

Recently, high recording density has become necessary for magnetic recording media and a thinner protective film of a magnetic recording medium capable of reducing spacing loss has been demanded.

For forming a protective film, a sputtering method generally has been employed. In order to attain high recording density, a protective film, too, has been made thin since there is requirement for a film thickness less than 10 nm. However, a film thickness less than 10 nm by a sputtering method cannot secure satisfactory corrosion resistance and durability. Accordingly, a plasma CVD method is mainly employed currently. At thinner film thicknesses of less than 6 nm, a conventional plasma CVD method may cause unsatisfactory corrosion resistance and durability. Consequently, a method has been explored to form a protective film capable of preserving satisfactory corrosion resistance and durability even for protective films of reduced thickness. On the other hand, film formation by means of a plasma CVD method causes, in an early stage of processing, surface damage on a magnetic layer beneath the protective film and impair magnetic performance and electromagnetic conversion characteristic.

Formation of a carbon protective film by means of a plasma CVD method, though exhibiting good durability and corrosion resistance, involves a problem of degraded resistance to gas adsorption. In order to deal with this problem, a method of forming a carbon protective film by means of a plasma CVD method has been proposed in which a bias voltage higher than −500 V is applied in an initial stage of depositing a protective film and a bias voltage not higher than −500 V is applied in a final stage of film deposition, as in Japanese Unexamined Patent Publication No. 2007-046115 and corresponding US Patent Application Publication No. 2007/0037014.

The conventional plasma CVD method mentioned above may cause unsatisfactory corrosion resistance and durability unless the bias voltage in the process of forming a protective film is lower than −120 V (absolute value is larger than 120 V). Although an elevated bias voltage (large absolute value) improves denseness and hardness of the formed film improving film quality, a very large bias voltage (large absolute value) during deposition induces conspicuous damage on the magnetic layer and formation of interface mixing layer. These phenomena conflict, in that the degradation of signals due to the damage exceeds the improvement in electromagnetic conversion characteristics obtained by the reduced film thickness. In addition, the mixing layer of the magnetic layer and the carbon layer formed at the interface does not contribute to corrosion resistance and inhibits additional thickness reduction in the carbon film. The proposal disclosed in US 2007/0037014 is apt to create this problem because a large bias voltage (large absolute value) is applied.

The present invention is directed to overcoming or at least reducing the effects of one or more of the problems set forth above.

### SUMMARY OF THE INVENTION

In view of the above problem, it is an object of the present invention to provide a method of forming a protective film in which a bias voltage of a large absolute value is applied solely in the later period of deposition of a carbon protective film, and improvement in electromagnetic conversion characteristic by virtue of reduced thickness of the protective film is accomplished without suffering damage on the magnetic layer. Another object of the invention is to provide a magnetic recording medium that exhibits both satisfactory electromagnetic conversion characteristics and corrosion resistance.

A method of forming a protective film according to the invention forms a carbon protective film by means of a high frequency plasma CVD method on a disk including at least a magnetic film formed on a nonmagnetic substrate, wherein a bias voltage in a range of −200 V to zero V is applied at the beginning of discharge in a process of forming the carbon protective film, and a bias voltage in a range of −500 V to −200 V is applied at the end of discharge. If a bias voltage higher than −200 V (an absolute value <200 V) is applied during the later period of discharge (the second step in two-step discharge sequence), a small effect is provided for improving quality of the carbon film through a high potential bias effect, and if a bias voltage not higher than −500 V (an absolute value >500 V) is applied, high energy ions pass through the protective film formed in the earlier stage of discharge to damage the magnetic film.

A magnetic recording medium according to the invention includes at least a magnetic film and a protective film provided on a nonmagnetic substrate, wherein the protective film is formed by the method of forming a protective film as stated above.

The invention controls the mixing layer formation at a magnetic film/protective film interface, deterioration of magnetic performance, and degradation of electromagnetic conversion characteristic, which were all difficult to avoid, to a minimal level.

### BRIEF DESCRIPTION OF THE DRAWINGS

The foregoing advantages and features of the invention will become apparent upon reference to the following detailed description and the accompanying drawings, of which:

FIG. 1 shows an example of constitution of a plasma CVD apparatus for use in the method of forming a protective film according to the invention;

FIG. 2 shows main discharge power and applied bias voltage in the method of forming a protective film according to the invention; and

FIG. 3 shows magnetic characteristics of a longitudinal magnetic recording medium manufactured by forming a hard carbon protective film according to a method of forming a protective film of the invention.

### DETAILED DESCRIPTION OF SPECIFIC EMBODIMENTS

Now, a preferred embodiment of a method of forming a protective film of the present invention will be described. A nonmagnetic substrate used in the invention can be selected from any nonmagnetic substrates used in common magnetic recording media, examples of which including substrates of NiP-plated aluminum alloy, strengthened glass, and crystallized glass. A magnetic film, too, can be selected from magnetic films used in common magnetic recording media, and preferably of a ferromagnetic material of an alloy containing at least cobalt and chromium.

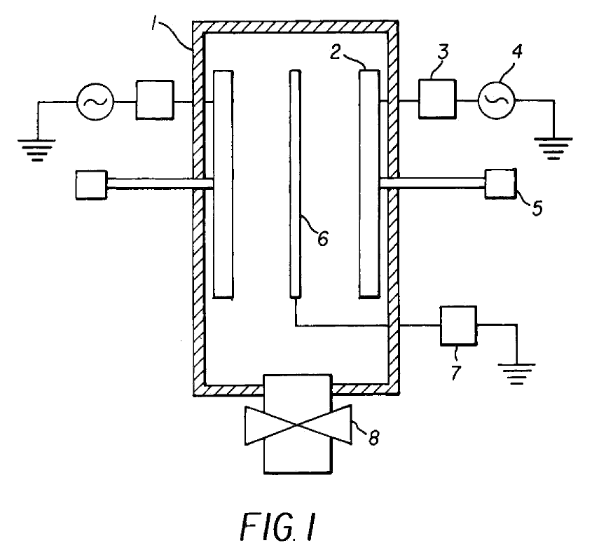

A protective film in the invention can be formed of diamond-like carbon (DLC), tetrahedral amorphous carbon (ta-C), amorphous carbon (a-C) or the like. A DLC film, in particular, exhibits excellent smoothness and high hardness, so is suited for a carbon protective film. A carbon protective film according to the present invention is formed by a high frequency plasma CVD method. FIG. 1 shows an example of construction of a plasma CVD apparatus that can be used in the method of forming a protective film according to the invention.

In the process of forming the protective film, magnetic recording medium 6 including at least a magnetic film formed on a nonmagnetic substrate is disposed between two electrodes 2 arranged opposing with one another in processing chamber 1. Mixed gas is supplied through mixed gas supply line 5 into processing chamber 1, and exhausted through main suction line 8.

A high frequency plasma CVD method uses a mixed gas of discharged gas and raw material gas for the deposition process. The raw material gas is preferably selected from hydrocarbon gases such as acetylene, ethylene, methane, and ethane. The discharge gas is preferably selected from rare gases such as argon, neon, and xenon.

Plasma is generated by applying a high voltage on electrode 2 and, by locating magnetic recording medium 6 in the plasma, a carbon protective film is formed on a magnetic film. Magnetic recording medium 6 is connected to high frequency bias power supply 7 and a bias voltage at a negative polarity is applied on magnetic recording medium 6 to improve durability of the protective film.

In the method according to the invention, a bias voltage in the range of 0 V to −200 V is applied at the beginning of the discharge, and a bias voltage in the range of −200 V and −500 V is applied at the end of the discharge. Application of a bias voltage in the range of 0 V to −200 V in the early stage of the discharge minimizes damage on the magnetic layer. The discharge is continued varying the bias voltage continuously or stepwise. At the end of the discharge, a bias voltage in the range of −200 V to −500 V is applied. This procedure provides a protective film of satisfactory durability.

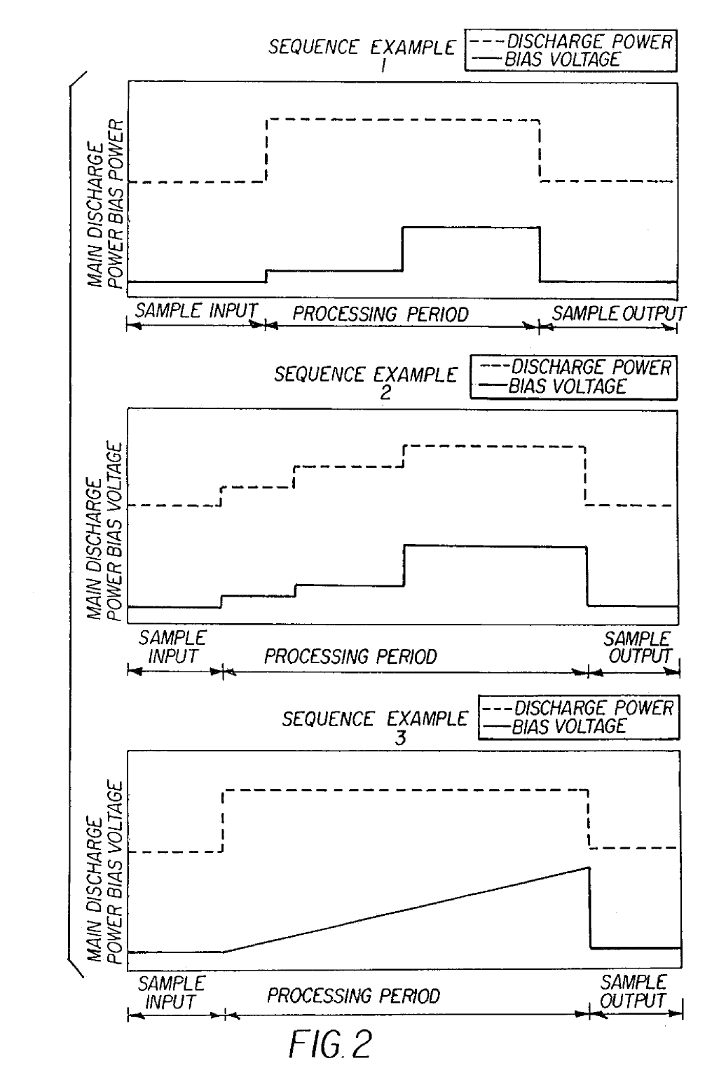

FIG. 2 shows examples of sequences in the process of forming a protective film according to the invention. The abscissa shows processing time and the ordinate shows discharge powers and bias voltages (absolute values). Sequence Example 1 shows a bias voltage application process in which the bias voltage is changed in two steps, and Sequence Example 2 shows a process in which the bias voltage is changed in three steps. In these sequence examples, discharge power, which affects characteristics of a magnetic layer, is also changed stepwise in synchronism with the bias voltage, which affects mainly damage on the magnetic layer. In Sequence Example 3, the bias voltage is varied continuously to change the property of the magnetic layer in a sloped shape. The discharge power here is constant as in Sequence Example 1.

A thickness of a carbon protective film formed by a method of forming a protective film according to the invention is preferably in the range of 0.1 nm to 6 nm. A film thickness thinner than 0.1 nm is apt to result in insufficient durability and corrosion resistance required for a protective layer. A film thickness thicker than 6 nm increases the distance between the magnetic layer surface and a magnetic head, resulting in difficulty in enhancing recording density.

Next, a magnetic recording medium according to the invention will be described. A magnetic recording medium of the invention comprises at least a magnetic film on a nonmagnetic substrate. A specific example of a structure of a magnetic recording medium comprises a nonmagnetic underlayer film on the substrate, a magnetic film on the nonmagnetic underlayer film, a carbon protective film formed over the magnetic film by the method of forming a protective film described above, and a liquid lubricant layer on the carbon protective film. The nonmagnetic substrate, magnetic film, and carbon protective film can be the same as those described above relating to the method of forming a protective film.

The nonmagnetic underlayer film is provided to control crystal orientation and grain size of the magnetic film, and is composed of a nonmagnetic underlayer metal of ruthenium or ruthenium alloy, for example. The nonmagnetic underlayer film and the magnetic film are formed by a vapor deposition method. The vapor deposition method can be a physical vapor deposition method or a chemical vapor deposition (CVD) method. The physical vapor deposition method can be sputtering or a vacuum evaporation method. So, the vapor deposition methods include sputtering, vacuum evaporation, and CVD. The sputtering method includes a DC (direct current) magnetron sputtering method and an RF (radio frequency) magnetron sputtering method.

The liquid lubricant layer can be obtained by applying a liquid lubricant of perfluoropolyether by a dip-coating method, for example.

### EXAMPLES

The present invention will be further explained with reference to specific examples according to embodiment of the invention.

The magnetic recording media of the following embodiment examples and comparative examples were fabricated by using a substrate of an amorphous strengthened glass substrate, forming an underlayer film of a chromium alloy by a sputtering method on the substrate, using a magnetic film formed of laminated films of 52Co-26Cr-14Pt-7B/65Co-14Cr-12Pt-9B, forming a protective film on the magnetic film through a sequence for each example shown below, and applying perfluoropolyether liquid lubricant on the protective film by a dip-coating method.

### Example 1

A protective film of this example was formed through a sequence of discharge and bias voltage application shown by Sequence Example 1 in FIG. 2 in which the application process of the bias voltage was in two stages and that of the main discharge power was in a single stage.

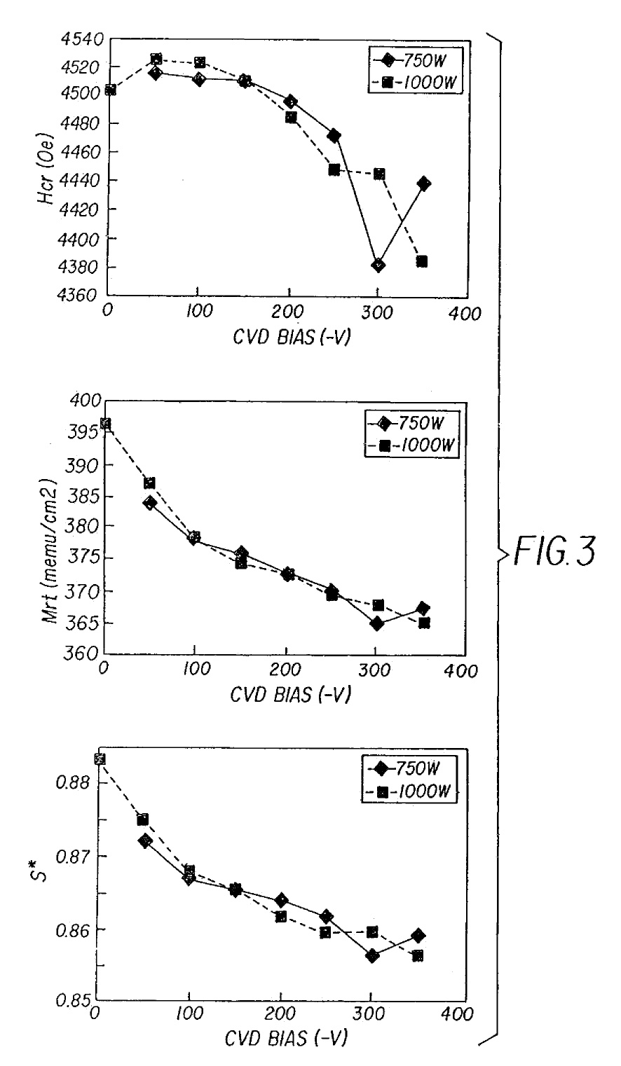

FIG. 3 shows the result of a study on the effect of various bias voltages immediately after beginning of discharge on magnetic properties of Hcr (remanent coercive force), Mrt (magnetic anisotropy), and S* (squareness ratio) in the cases of the main discharge power of 750 W and 1,000 W.

FIG. 3 shows that lower bias voltage in initial growth CVD improves Hcr, Mrt, and S* more despite the same process of magnetic layer formation. This means that a thinner magnetic layer is practically sufficient to attain the target magnetic properties. A thinner magnetic layer reduces media noise in measuring electromagnetic conversion characteristics and results in improvement of the electromagnetic conversion characteristics including SN ratio.

Table 1 shows the results of a study on electromagnetic conversion characteristics of magnetic recording media manufactured by forming a protective film through Sequence Example 1 (Experimental Examples 2 through 5), as well as the result of a study on electromagnetic conversion characteristics of a magnetic recording medium manufactured by forming a protective film through a single step process for comparison (Experimental Example 1). Experimental Examples 2 through 5 have a total thickness of the protective film of a constant value of 3 nm, wherein the thickness and bias voltage in the first step were varied. The bias voltage in the second step was a constant value of −270 V.

TABLE 1

| Ex- | T (nm) | Tₜₒₜ | V_{bias} | V_{bias} | TAA | Res | OW | SN |
|---|---|---|---|---|---|---|---|---|
| ample | 1st step | (nm) | 1st step | 2nd step | (mV) | % | (dB) | (dB) |
| 1 | 0 | 3 | — | −270 V | 0.731 | 72.27 | 36.13 | 20.47 |
| | (0%) | | | | | | | |
| 2 | 0.8 | 3 | 0 V | −270 V | 0.724 | 72.50 | 36.69 | 20.71 |
| | (27%) | | | | | | | |
| 3 | 0.8 | 3 | −50 V | −270 V | 0.713 | 72.18 | 36.27 | 20.61 |
| | (27%) | | | | | | | |
| 4 | 1.4 | 3 | −50 V | −270 V | 0.723 | 72.36 | 36.15 | 20.63 |
| | (47%) | | | | | | | |
| 5 | 0.8 | 3 | −10 V | −270 V | 0.708 | 71.89 | 36.36 | 20.59 |
| | (27%) | | | | | | | |

1st column: Experimental Example
2nd column: Thickness in first step (nm) (proportion %)
3rd column: Total thickness of protective film (nm)
4th column: Bias voltage in first step
5th column: Bias voltage in second step
6th column: TAA (track averaged amplitude)
7th column: Res (Resolution)
8th column: OW (overwrite property)
9th column: SN (signal to noise ratio)

Table 1 clearly shows that both the characteristics of OW and SN have been improved in the magnetic recording media of Experimental Examples 2 through 5 as compared with the medium formed by the single step process, which is a comparative example. The amount of improvement reached a maximum 0.5 dB in OW and maximum 0.3 dB in SN.

Sequence Examples 2 and 3 of the processes shown in FIG. 2 exhibited similar results to those in Sequence Example 1.

The present invention provides a method of forming a carbon protective layer that exhibits satisfactory corrosion resistance and durability even in a thin protective film without adversely affecting electromagnetic conversion characteristics.

Thus, a method of forming a carbon protective layer has been described according to the present invention. Many modifications and variations may be made to the techniques and structures described and illustrated herein without departing from the spirit and scope of the invention. Accordingly, it should be understood that the methods and apparatus described herein are illustrative only and are not limiting upon the scope of the invention.

### DESCRIPTION OF SYMBOLS

1: processing chamber
2: electrode
3: high frequency matching circuit
4: high frequency power supply
5: raw material gas supply line
6: substrate
7: high frequency bias power supply
8: main suction line

What is claimed is:

1. A method of forming a carbon protective film on a disk including at least a magnetic film on a nonmagnetic substrate, comprising:
placing a disk including at least a magnetic film on a nonmagnetic substrate in a high frequency plasma CVD chamber;
applying a bias voltage in a range of −200 V to zero V by means of high frequency plasma CVD method at the beginning of discharge in a process of forming a carbon protective film; and
applying a bias voltage in a range of −500 V to −200 V by means of high frequency plasma CVD method at the end of discharge in the process of forming the carbon protective film.

2. The method of forming a protective film according to claim 1, wherein the bias voltage is changed in two or more steps.

3. The method of forming a protective film according to claim 1, wherein the bias voltage is changed continuously.

4. The method of forming a protective film according to claim 1, wherein a thickness of the protective film is in a range of 0.1 to 6 nm.

5. The method of forming a protective film according to claim 2, wherein a thickness of the protective film is in a range of 0.1 to 6 nm.

6. The method of forming a protective film according to claim 3, wherein a thickness of the protective film is in a range of 0.1 to 6 nm.

7. A magnetic recording medium having at least a magnetic film and a protective film on a nonmagnetic substrate, wherein the protective film is formed by a high frequency plasma CVD, in which a bias voltage in a range of −200 V to zero V is applied by means of high frequency plasma CVD method at the beginning of discharge and a bias voltage in a range of −500 V to −200 V is applied by means of high frequency plasma CVD method at the end of discharge.

8. The magnetic recording medium according to claim 7, wherein the bias voltage is changed in two or more steps during formation of the protective film.

9. The magnetic recording medium according to claim 7, wherein the bias voltage is changed continuously during formation of the protective film.

10. The magnetic recording medium according to claim 7, wherein the thickness of the protective film is in a range of 0.1 to 6 nm.
